(19) United States
(12) Patent Application Publication
(10) Pub. No.: US 2017/0110816 A1
(43) Pub. Date: Apr. 20, 2017

(54) CLIP AND ELECTRICAL CONNECTOR ASSEMBLY

(71) Applicant: FOXCONN INTERCONNECT TECHNOLOGY LIMITED, Grand Cayman (KY)

(72) Inventors: MIN TAO, Kunshan (CN); QUAN WANG, Kunshan (CN); CHENG-CHI YEH, New Taipei (TW)

(21) Appl. No.: 15/295,990

(22) Filed: Oct. 17, 2016

(30) Foreign Application Priority Data
Oct. 16, 2015 (CN) 201520799373.X

(51) Int. Cl. H01R 12/70; H01R 13/73; H05K 7/10

(52) U.S. Cl. CPC H01R 12/7076; H05K 7/1053; H01R 13/73; H01R 12/7058

(57) ABSTRACT

A clip is used for carrying a chip module to assemble to an electrical connector along a vertical direction. The clip includes a retaining mechanism retaining the chip module and a central opening provided for a part portion of the chip module going through. The clip has an anti-mismating member. When the clip is assembled to the electrical connector by itself disposed in a right-to-left direction perpendicular to the vertical direction or reversely relative to a front-to-back direction perpendicular to the vertical direction, the anti-mismating member stops the clip to be assembled to the electrical connector.

### BACKGROUND OF THE INVENTION

1. Field of the Invention

The present invention generally relates to a clip and an electrical connector assembly comprising the clip.

2. Description of Related Art

Chinese patent issued No. 103855506 discloses an electrical connector. The electrical connector is used for connecting with a chip module. The electrical connector has a base portion, a plurality of conductive terminals received in the base portion and a clip carrying the chip module to assemble to the base portion in a vertical direction. The clip is configured as a rectangular frame. The clip has a central opening provided for a wafer of the chip module going through. The clip configured as rectangular structure, generally, users can not recognize the right mounting way. In this condition, when users press downwardly on the clip, the chip module or terminals of the base portion is/are easy to be destroyed.

Therefore, a clip having an anti-mismating member and an electrical connector assembly are desired hereinafter.

### SUMMARY OF THE INVENTION

Accordingly, an object of the present invention is to provide a clip and an electrical connector, the clip has an anti-mismating member, the electrical connector has the aforementioned clip.

In order to achieve the object set forth, a clip is used for carrying a chip module to assemble to an electrical connector along a vertical direction. The clip comprises a retaining mechanism retaining the chip module and a central opening provided for a part portion of the chip module going through. The clip has an anti-mismating member. When the clip is assembled to the electrical connector by itself disposed in a right-to-left direction perpendicular to the vertical direction or reversely relative to a front-to-back direction perpendicular to the vertical direction, the anti-mismating member stops the clip to be assembled to the electrical connector.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of a clip of a first embodiment in the present invention;

FIG. 2 is another perspective view of the clip shown in FIG. 1;

FIG. 3 is a perspective view of an electrical connector assembly having the clip shown in FIG. 1;

FIG. 4 is a perspective view of a clip and a chip module of the electrical connector assembly shown in FIG. 3, wherein the chip module is not assembled to the clip;

FIG. 5 is a part exploded perspective view of the electrical connector assembly shown in FIG. 3, wherein the chip module is assembled and retained to the clip;

FIG. 6 is another perspective view of the chip module and the clip shown in FIG. 5;

FIG. 7 is a perspective view of the electrical connector assembly shown in FIG. 5, wherein the chip module and the clip are received in an insulating housing thereof,

FIG. 8 is a side view of the electrical connector shown in FIG. 5, wherein the clip which carrying the chip module is reversely/incorrectly assembled to the insulating housing in a front-to-back direction;

FIG. 8(A) is a cross-sectional view of the electrical connector shown in FIG. 5, wherein the clip which carrying the chip module is correctly assembled to the insulating housing in a front-to-back direction;

FIG. 9 is a perspective view of a clip and a chip module of an electrical connector assembly of a second embodiment in the present invention, wherein the chip module is not assembled to the clip;

FIG. 10 is another perspective view of a clip and a chip module shown in FIG. 9;

FIG. 11 is a part exploded perspective view of the electrical connector of the second embodiment in the present invention, wherein the chip module is assembled to the clip;

FIG. 12 is a perspective view of the electrical connector shown in FIG. 11, wherein the clip and the chip module are received in the insulating housing; and

FIG. 13 is a schematic diagram of the electrical connector assembly shown in

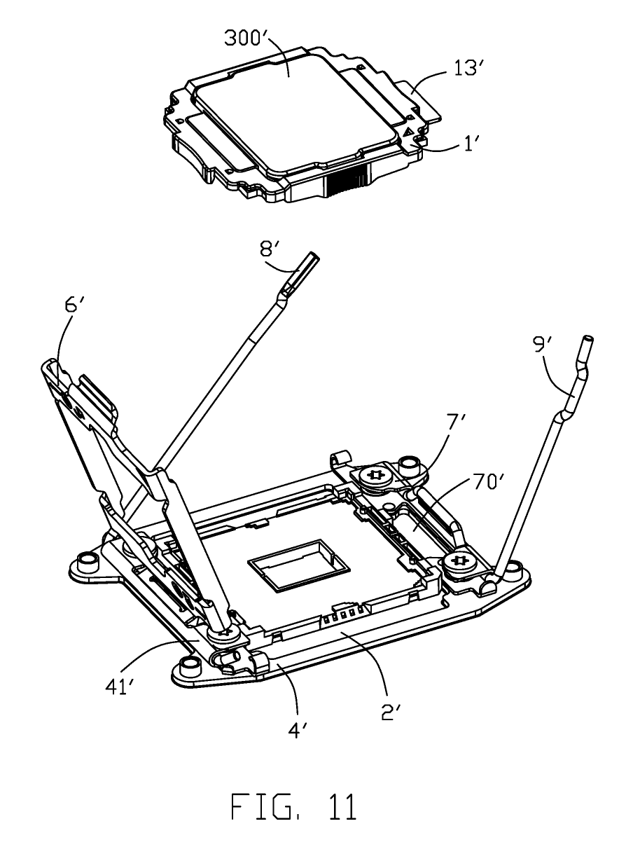

FIG. 11, wherein the clip carrying the chip module is reversely assembled to the insulating housing in a front-to-back direction.

### DETAILED DESCRIPTION OF THE INVENTION

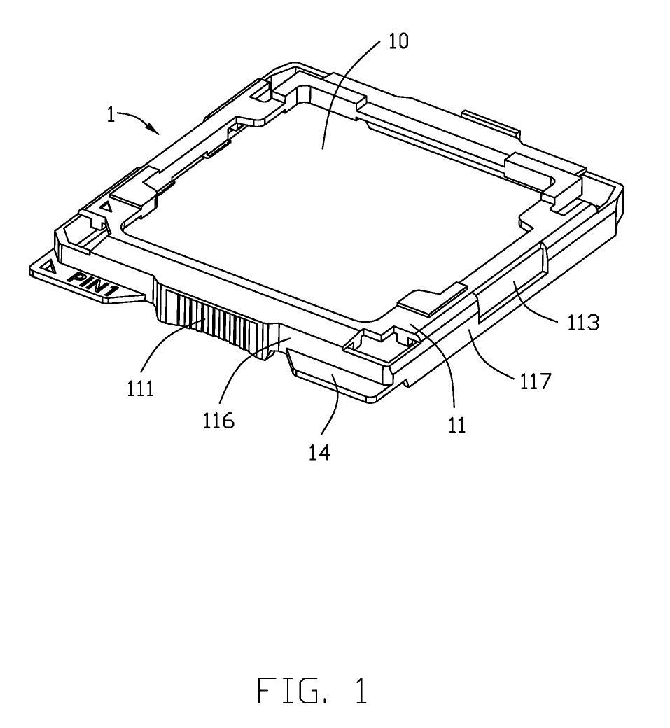

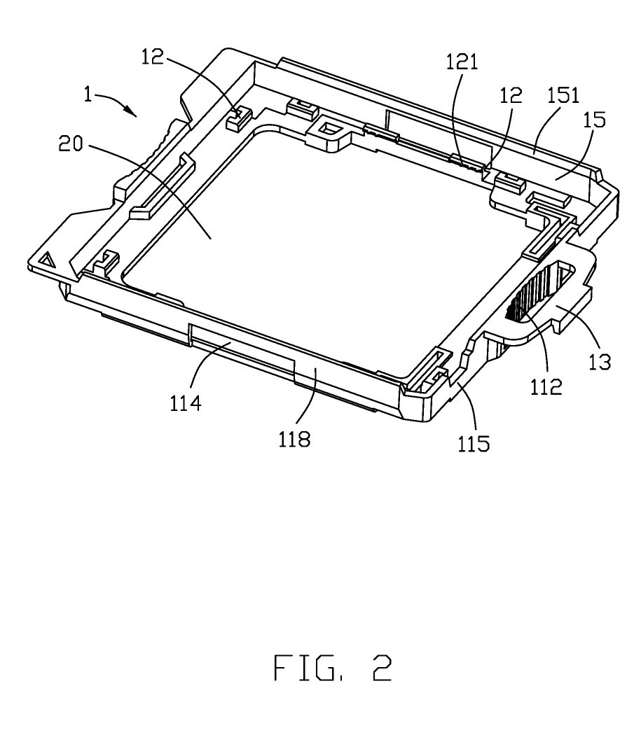

Reference will now be made in detail to the preferred embodiment of the present invention. Referring to FIG. 1 and FIG. 2, a clip 1 is provided in the present invention. The clip 1 is used for carrying a chip module 300. A clip in tradition is initially mounted to a cover of an electronic device, then the cover carries the clip within a chip module therein to assemble to the electronic device. Differently, the clip 1 in the present invention directly carries the chip module 300 to assemble to the electrical connector along a vertical direction without cooperating with a cover. The clip 1 has a retaining mechanism (not labeled) provided for retaining the chip module 300 and a central opening 10 provided for a part portion of the chip module 300 going through. The structure of the retaining mechanism will be described in detail herein the after. The clip 1 has a main body 11 including an upper surface (not labeled) and an opposite lower surface (not labeled). The main body 11 has the aforementioned central opening 10 and a plurality of limiting blocks 12 extending downwardly from the lower surface thereof and located in a peripheral areal of the central opening 10. The plurality of limiting blocks 12 are together to form a limiting room 20 to carry the chip module 300. At least some of the limiting blocks 12 have latching portions 121 protruding into the limiting room 20 from free ends thereof to latching the chip module 300. The main body 11, the limiting blocks 12, the latching portions 121, the limiting room 20 and the central opening 10 are together to form the retaining mechanism.

In order to grab the clip 1, the main body 11 has a pair of grabbing portions 111, 112/113, 114 extending downwardly from two opposite sides of the central opening 10. The clip 1 has a front face 115, a rear face 116 opposite to the front face 115 and two side faces 117, 118 connecting the front face 115 and the rear face 116. The pair of grabbing portions 111, 112 may be respectively disposed at the front face 115 and the rear face 116. The pair of grabbing portions 113, 114 may be respectively disposed at the two side faces 117, 118. Users can grab at a pair of the grabbing portions 111, 112/113,114 to grab the clip 1 when the four faces 115, 116, 117, 118 are all provided with the grabbing portions.

The main improvement of the present invention is that the clip 1 has an anti-mismating member. The clip 1 has a first protruding portion 13 extending forwardly beyond the front face 115 and at least a second protruding portions 14 extending rearwardly beyond the rear face 116. Two second protruding portions 14 are respectively disposed at two sides of the rear face 116 in the present preferred embodiment. The first protruding portion 13 and the second protruding portion 14 are together to function as the anti-mismating member. Of course, in other embodiments, the clip may only dispose the first protruding portion 13 or the second protruding portion 14. The shape, size and number of the first protruding portion 13 and the second protruding portion 14 are depended on specific conditions. The anti-mismating member also may extend beyond the two side faces 117, 118 of the clip 1.

The main body 11 has at least one extending portion 15 extending downwardly and located at a side of the central opening 10. An outer surface of the extending portion 15 forms the front face 115, the rear face 116 or the side face 117/118. The extending portion 15 has an inclined guiding face 151 in an inner side thereof.

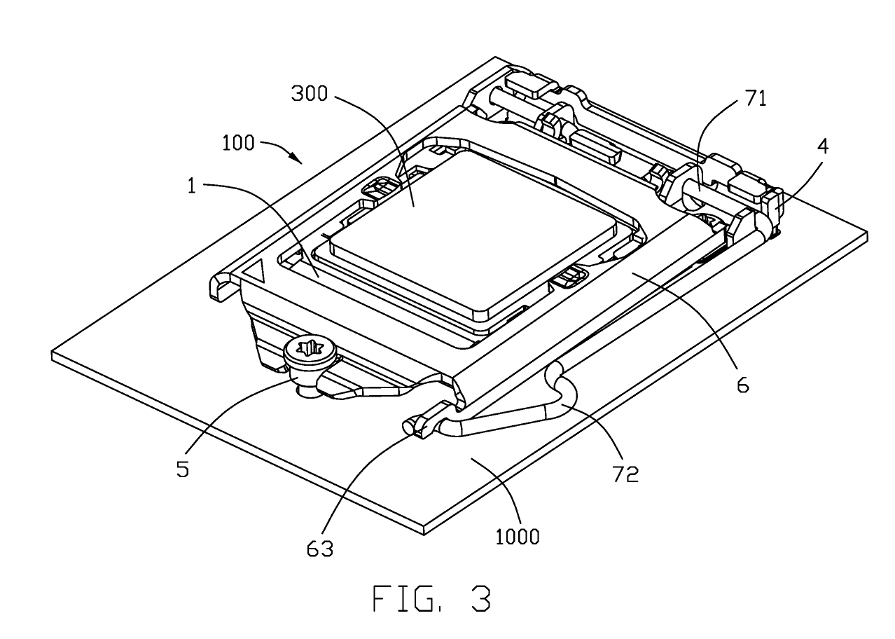

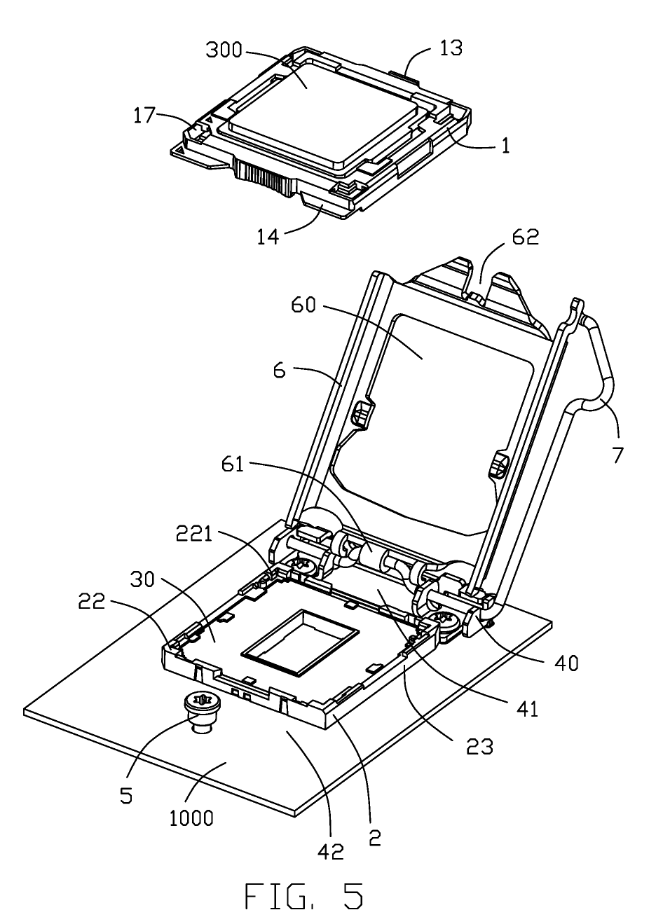

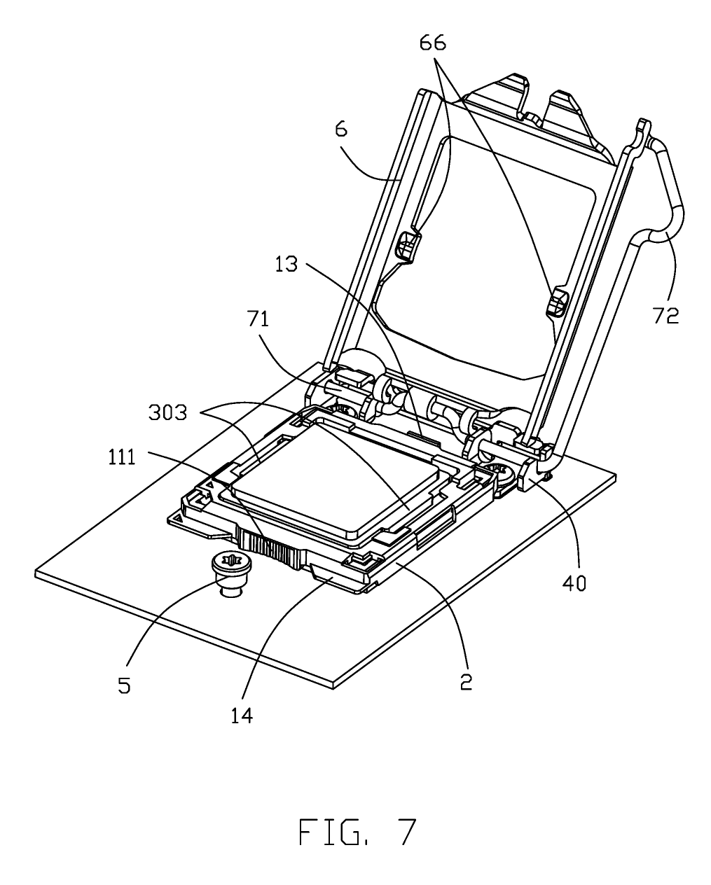

Referring to FIG. 3 to FIG. 8, an electrical connector assembly 100 is provided in the present preferred embodiment. The electrical connector 100 is used for connecting with a chip module 300. The chip module 300 has a base plate 301 and a protruding portion 302 protruding upwardly therefrom. The chip module 300 has a stepping portion 303 disposed at a lateral side of the protruding portion 302. Referring to FIG. 3, FIG. 5 and FIG. 7, the electrical connector assembly 100 comprises an electrical connector (not labeled), the aforementioned clip 1 mounted to the electrical connector and a printed circuit board 1000. The electrical connector has an insulating housing 2, a plurality of conductive terminals (not labeled) retained in the insulating housing 2, a connecting/retaining member 4 disposed at a side of the insulating housing 2, a retaining/connecting member 5 disposed at another side of the insulating housing 2 opposite to the connecting member 4 and a cover 6 pivoted to the connecting member 4 and retained to the retaining member 5. The insulating housing 2, the connecting member 4 and the retaining member 5 are all retained onto the printed circuit board. The retaining member 5 is separated from the insulating housing 2. The cover 6 has a latching slot 62 latching with the retaining member 5. The cover 6 further includes a pair of pressing plates 66 downwardly pressing the stepped portions 303 of the chip module 300 for retaining the chip module 300 in position within the housing 2.

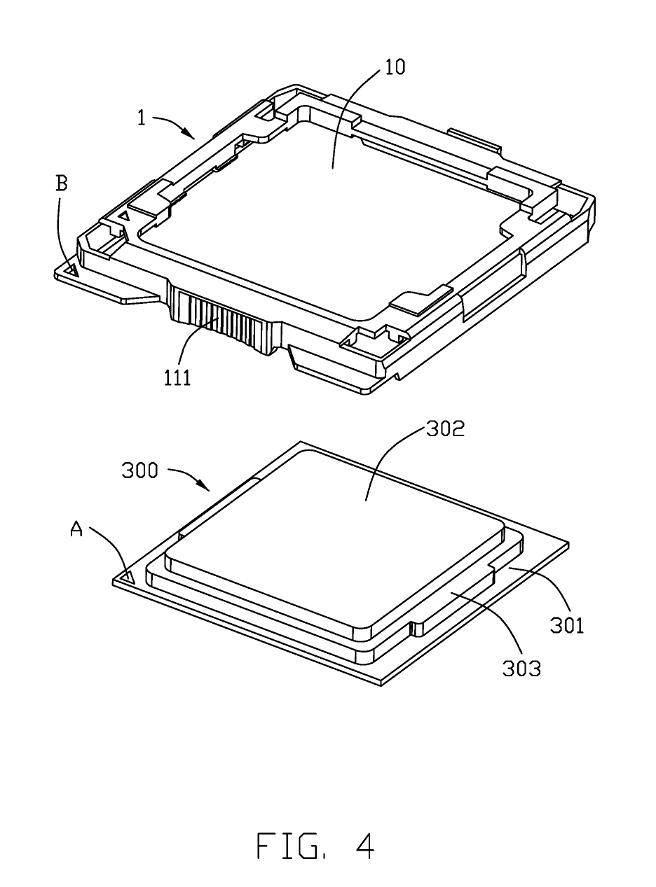

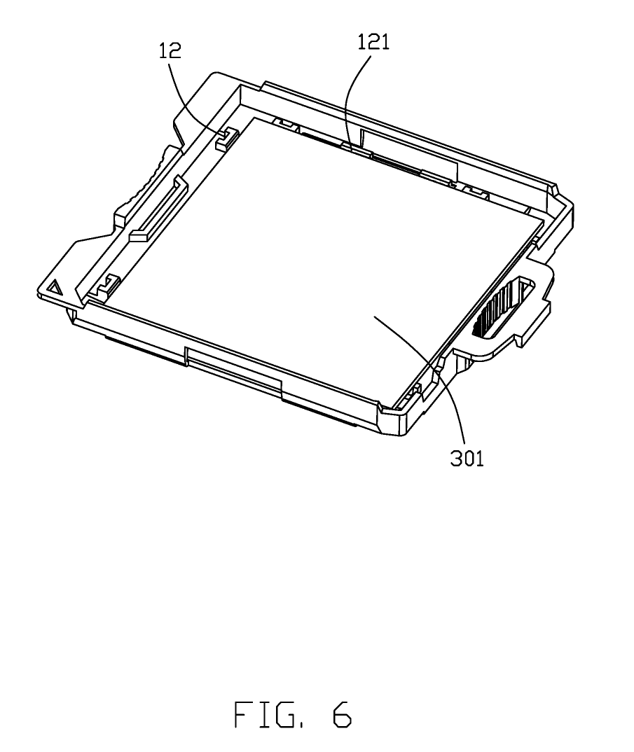

Referring to FIG. 4 to FIG. 7, the clip 1 is used for carrying the chip module 300 to assemble to the insulating housing 2 in a vertical direction. Referring to FIG. 5 and FIG. 6, the base plate 301 is entirely received in the limiting room 20 when the chip module 300 is assembled in the clip 1. The protruding portion 302 protrudes upwardly beyond the upper surface of the main body 11 from the central opening 10. The plurality of limiting blocks 12 are disposed at a peripheral side of the base plate 301. The latching portions 121 latch on a lower surface of the base plate 301. That is to say, the chip module 300 is limited by the main body 11 and the latching portions 121 along an up-to-down direction. In the present invention, the up-to-down direction is just the vertical direction.

Referring to FIG. 5 and FIG. 7, the insulating housing 2 is configured as rectangular shape and has an accommodating cavity 30. The insulating housing 1 has side walls 23 defining the accommodating cavity 30. The conductive terminals are exposed to the accommodating cavity 30. The insulating housing 2 has four guiding posts 22 extending upwardly and disposed at four corners thereof, respectively. The guiding posts 22 are configured as L-shaped so as to cooperate with four corners of the base plate 301 of the chip module 300. The guiding post 22 has a guiding face 221 disposed at an inner side thereof. The clip 1 has four guiding holes 17 at four corners and corresponding to the four guiding posts 22. Further more, the electrical connector assembly 100 has a receiving room and a stopping structure corresponding to the anti-mismating member. In the present embodiment, the clip 1 has the first protruding portion 13 and the second protruding portion 14. The connecting member 4 has a first receiving room 41 to receive the first protruding portion 13. The space between the retaining member 5 and the insulating housing 2 forms a second receiving room 42 receiving the second protruding portion 14. That is to say, the first receiving room 41 and the second receiving room 42 are together to form the receiving room. The retaining member 5 and the connecting member 4 are together to function as the stopping structure. After finishing the assembly, the extending portion 15 is located at an outer side of the side wall 23. The guiding posts 22 are received in the guiding holes 17. The anti-mismating members 13, 14 are received in the receiving rooms 41, 42.

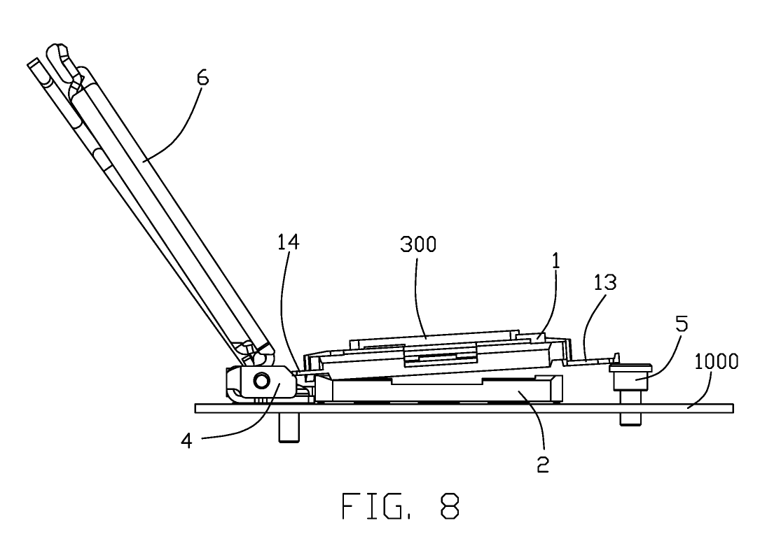

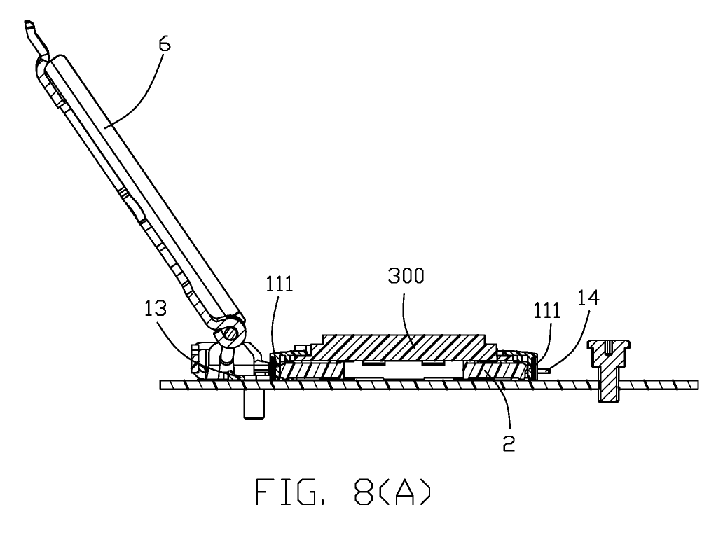

Referring to FIG. 8, the clip 1 has two opposite first side walls and two opposite second side walls connecting with the first side walls. The first side wall extends along a front-to-back direction perpendicular to the vertical direction. In the present invention, the retaining member 5 and the connecting member 4 are arranged along the front-to-back direction. The second side wall extends along a transverse direction perpendicular to the front-to-back direction and the vertical direction. When the clip 1 is mounted to the electrical connector by itself turned over along the front-to-back direction, the first protruding portion 13 is stopped by the retaining member 5, the second protruding member 14 is stopped by the connecting member 4, thereby the clip 1 is stopped by the first protruding portion 13 and the second protruding member 14 from being assembled to the insulating housing 2. Of course, in other embodiments, the electrical connector assembly 100 may only has the first protruding portion 13 and the first receiving room 41, or only has the second protruding portion 14 and the second receiving room 42, or both has the two kind of anti-mismating structures but the first protruding portion 13 and the retaining portion 5 does not have anti-mismating function due to the first protruding portion 13 cannot contact with the retaining member 5 when the clip 1 is assembled to the electrical connector by itself turned over along the front-to-back direction. The disposition of the position, shape and number of the anti-mismating member, the receiving room and the stopping structure are depended on a specific condition.

Combined with FIG. 3, the cover 6 is rotated initially and then retained to the retaining member 5. The connecting member 4 has a rocking bar 7 rotated to retain the cover 6. The rocking bar 7 has a rotating portion 71 pivoted to a main portion 40 of the connecting member 4 and an operating portion 72 perpendicular to the rotating portion 71. The cover 6 has an opening 60 from which the chip module 300 is exposed to an external, a bending portion 61 pivoted to the crank section (not labeled) of the rotating portion 71 and a fixing portion 63 used for fixing the operating portion 72. The rotating portion 71 downwardly presses on the cover 6 when the operating portion 72 is rotated to be retained by the fixing portion 63.

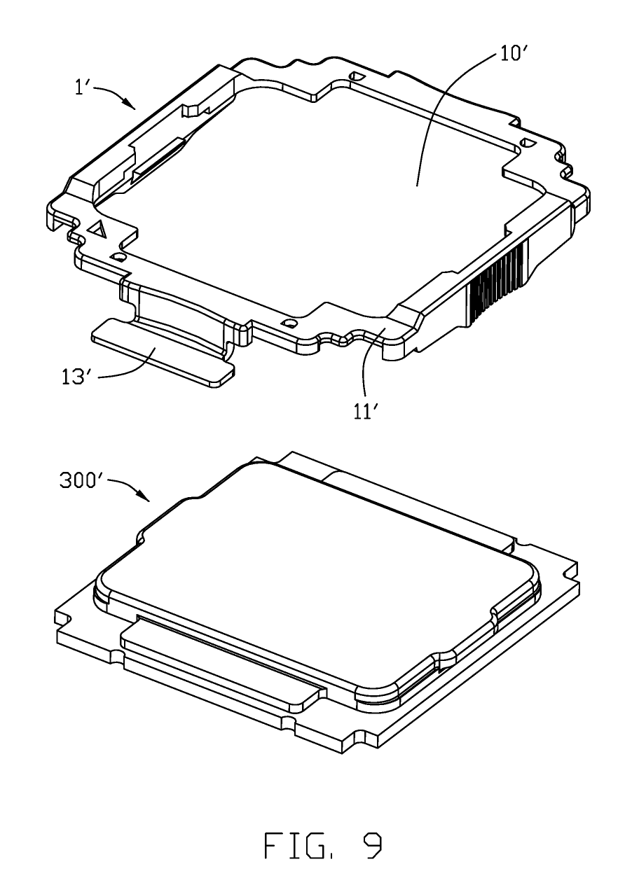

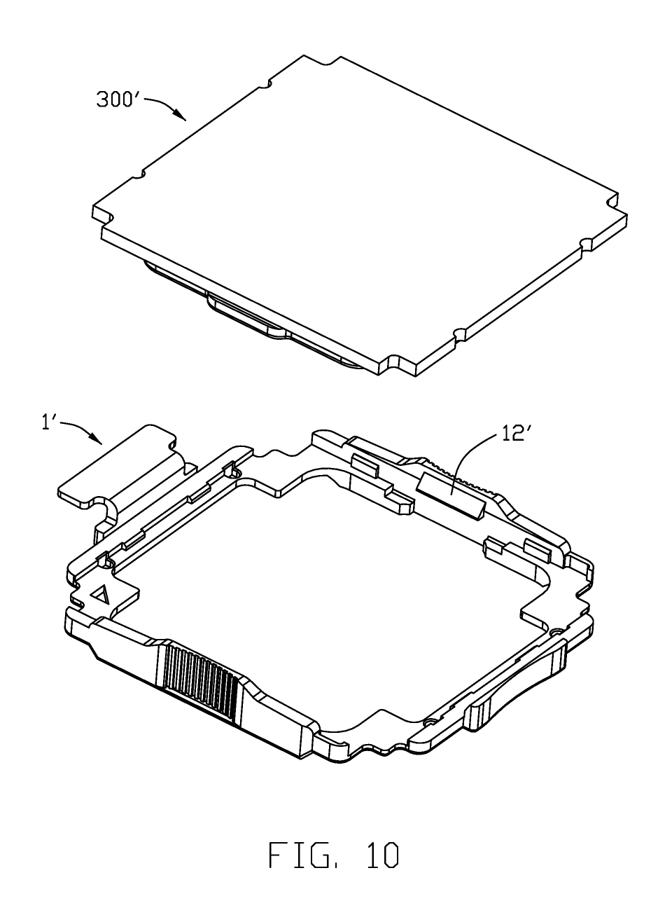

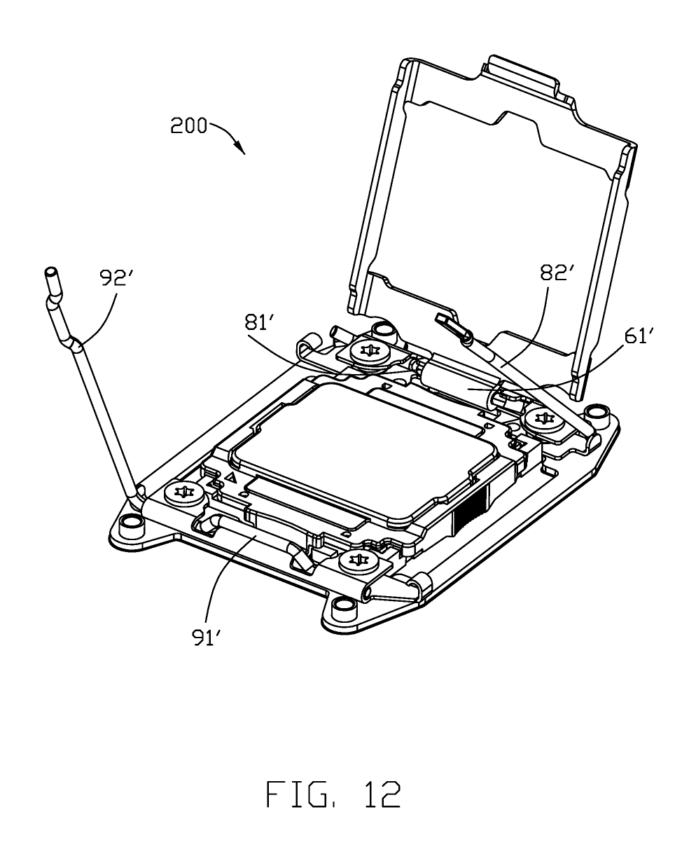

The aforementioned description is a first embodiment of the present invention. Referring to FIG. 9 to FIG. 13, a second embodiment of the present invention will be described in detail herein the after.

The second embodiment is provided with an electrical connector assembly 200. The electrical connector assembly 200 is used for connecting with a chip module 300′ and comprises an electrical connector (not labeled) and a clip 1′ mounted thereto. The electrical connector has an insulating housing 2′, a plurality of conductive terminals (not shown) retained in the insulating housing 2′, a base/connecting/retaining member 4′ configured as a frame structure and surrounding the insulating housing 2′, a cover 6′ pivoted to the base member 4′ and a retaining/connecting member 7′ retaining the cover 6′. The base member 4′ has a connecting member 41′ disposed at a lateral side of the insulating housing 2′. The cover 6′ is pivoted to the connecting member 41′. The retaining member 7′ is mounted at another lateral side of the insulating housing 2′ opposite to the connecting member 41′. The connecting member 41′ and the base member 4′ may be manufactured as two pieces or one piece. The retaining member 7′ and the base member 4′ may be manufactured as two pieces or one piece. The connecting member 41′ has a first rocking bar 8′ used for retaining the cover 6′. The retaining member 7′ has a second rocking bar 9′ used for retaining the cover 6′. The first rocking bar 8′ has a first rotating portion 81′ pivoted to the connecting member 41′ and a first operating portion 82′ perpendicular to the first rotating portion 81′. The second rocking bar 9′ has a second rotating portion 91′ pivoted to the retaining member 7′ and a second operating portion 92′ perpendicular to the second rotating portion 92′. The cover 6′ has a bending portion 61′ pivoted to the first rotating portion 81′.

The clip 1′ is used for carrying the chip module 300′ to assemble to the insulating housing 2′ along a vertical direction. The clip 1′ has a retaining mechanism retaining the chip module 300′ and a central opening 10′ provided for the chip module 300′ going through. The retaining mechanism at least comprises a main body 11′ of the clip 1′ and a plurality of latching portions 12′ latching on a lower surface of the chip module 300′. The clip 1′ has an anti-mismating member 13′. The retaining member 7′ has a receiving room 70′ to receive the anti-mismating member 13′.

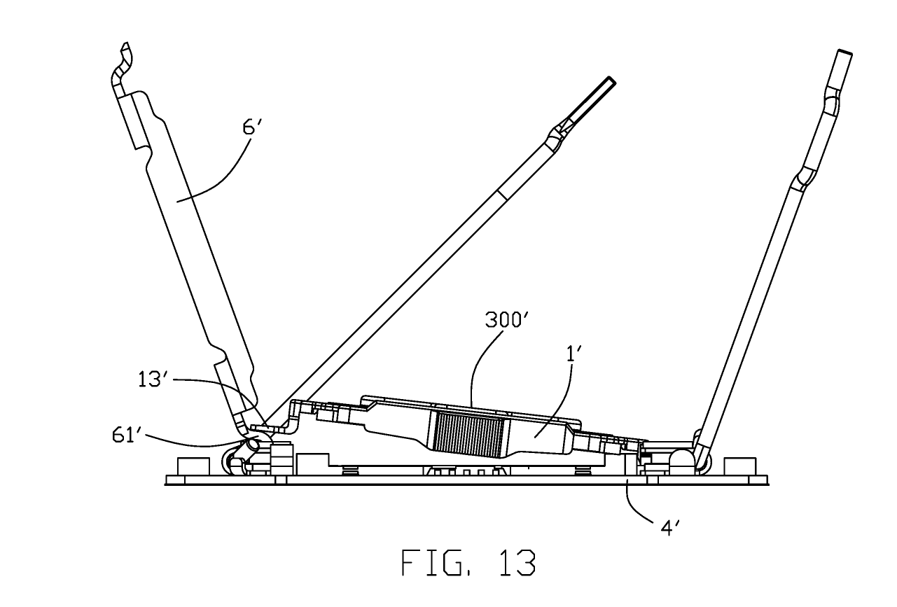

Referring to FIG. 13, the clip 1′ has two opposite first side walls and two opposite second side walls connecting with the first side walls. The first side wall extends along a front-to-back direction perpendicular to the vertical direction. In the present invention, the retaining member 7′ and the connecting member 41′ are arranged along the front-to-back direction. The second side wall extends along a transverse direction perpendicular to the front-to-back direction and the vertical direction. When the clip 1′ is assembled by itself turned over along the front-to-back direction, the anti-mismating member 13′ is stopped by the bending portion 61′, whereby the clip 1′ is stopped from assembling to the insulating housing 2′. That is to say, the bending portion 61′ is just functioned as a stopping structure.

When the clip 1′ and the chip module 300′ are received in the electrical connector, the cover 6′ is rotated to cover in a predetermined position initially, the first rocking bar 8′ and the second rocking bar 9′ are rotated to fixing the cover 6′ at last. The first rotating portion 81′ and the second rotating portion 9′ are respectively downwardly presses on two opposite sides of the cover 6′ to make the cover 6′ downwardly press on the chip module 300′, thereby the chip module 300′ is disposed in a proper position at last.

Notably, the clip 1, 1′ may be made of plastic material having excellent elasticity or metal material. The retaining mechanism of the clip 1 described in the first embodiment is also fit for the clip 1′ of the second embodiment. In different conditions, in the first embodiment and the second embodiment, the connecting member 4, 41′ or the bending portion 61, 61′ may function as the stopping structure, or the connecting member 4, 41′ and the bending portion 61, 61′ may be together to function as the stopping structure. When the insulating housing 2, 2′ is configured as square shape, in a preferred embodiment, a fool-proof member is disposed at the two opposite side walls of the insulating housing 2 or on the circuit board 1000 at two sides of the insulating housing 2 in the first embodiment, as well, an anti-mismating member is disposed at the two opposite side walls of insulating housing 2′ or on the base member 4′ at two sides of the insulating housing 2′ in the second embodiment. Of course, the anti-mismating member may be disposed at the right side or the left side of the clip 1, 1′ or both of the two sides. The stopping structure is disposed on the right side wall or the left side wall or the circuit board 1000 at two sides of the insulating housing or the base member 4′ at two sides of the insulating housing.

In conclusion, the stopping structure and the anti-mismating member are cooperated to protect the chip module 300, 300′ and the conductive terminals from being destroyed. In this embodiment such an anti-mismating is provided between the clip 1 and the connector which includes the housing 2, the connecting member 4 and the retaining member 5. In other words, such anti-mismating may occurs between the clip 1 and the housing 2, or between the clip 1 and the connecting member 4, or between the clip 1 and the retaining member 4. Notably, such a anti-mismating is the solid structure which efficiently prohibits the incorrect/misoriented mating between the clip and the connector as a hard anti-mismating mechanism. On the other hand, a soft anti-mismating mechanism is required between the chip module 300 and the clip 1 by using indicating arrow A on one corner of the chip module 300 and another indicating arrow B on the corresponding corner of the clip 1 for having the user know which orientation of the chip module 300 should be used within the clip 1. Understandably, because the chip module 300 is of a standard configuration, it is improper to reconfigure its periphery to form either a recess or a protrusion therewith for resulting in the solid/hard anti-mismating mechanism. Instead, using the indicating arrow on both parts for assembling therebetween as the soft anti-mismating mechanism can only guide the user how to assemble those two parts but not structurally prohibit mis-mating physically if the user still uses in an incorrect orientation. In this embodiment, the indicating arrow A on the chip module 300 is of a printed manner because the chip module 300 is essentially unchangeably solid while the indicating arrow B on the clip 1 is of a hollow manner for easy identification because the clip 1 is injection molded by plastic. In this invention, such a soft anti-mismating mechanism between the chip module 300 and the clip 1, and a hard anti-mismating mechanism between the clip 1 and the connector 100, are used for achieving the complete anti-mismating function of the whole combined connector assembly.

It is to be understood, however, that even though numerous characteristics and advantages of the present invention have been set forth in the foregoing description, together with details of the structure and function of the invention, the disclosure is illustrated only, and changes may be made in detail, especially in matters of shape, size, and arrangement of parts within the principles of the invention to the full extent indicated by the broad general meaning of the terms in which the appended claims are expressed.

We claim:

1. A clip used for carrying a chip module to assemble to an electrical connector along a vertical direction, comprising:
a retaining mechanism provided for retaining the chip module; and
a central opening provided for a part portion of the chip module going through;
wherein the clip has an anti-mismating member used for preventing the clip from being assembled to the electrical connector in a wrong way.

2. The electrical connector as claimed in claim 1, wherein the clip has a front face and a first protruding portion extending forwardly beyond the front face, and the first protruding portion is functioned as the anti-mismating member.

3. The electrical connector as claimed in claim 1, wherein the clip has a rear face and a second protruding portion extending rearwardly beyond the rear face, and the second protruding portion is functioned as the anti-mismating member.

4. The electrical connector as claimed in claim 2, wherein the clip has a rear face and a second protruding portion extending rearwardly beyond the rear face, and the second protruding portion is functioned as the anti-mismating member.

5. The electrical connector as claimed in claim 1, wherein the clip has a main body defining the central opening, and a pair of grabbing portions extending downwardly from the main body and disposed at two opposite sides of the central opening

6. The electrical connector as claimed in claim 1, wherein the clip has a main body defining the central opening and a plurality of limiting blocks extending downwardly from a lower surface of the main body and located at a peripheral area of the central opening, and the plurality of limiting blocks are together to form a limiting room to carry the chip module.

7. The electrical connector as claimed in claim 6, wherein some of the limiting blocks have latching portions extending from free ends thereof to latch with the chip module, the main body, the limiting blocks, the latching portions, the limiting room and the central opening being together to form the retaining mechanism.

8. An electrical connector assembly comprising:
an electrical connector having an insulating housing and a plurality of conductive terminals retained thereto; and
a clip carrying a chip module to assemble to the insulating housing along a vertical direction, the clip having a retaining mechanism retaining the chip module and a central opening provided for the chip module going through;
wherein the clip has an anti-mismating member, the electrical connector assembly has a receiving room and a stopping structure correspond to the anti-mismating member; when the clip is normally assembled to the electrical connector, the anti-mismating member is received in the receiving room, when the clip is assembled to the electrical connector in a wrong way, the anti-mismating member is stopped by the stopping structure, whereby the clip is stopped to be assembled to the insulating housing.

9. The electrical connector assembly as claimed in claim 8, wherein the electrical connector has a connecting member disposed at a lateral side of the insulating housing and a retaining member disposed at another lateral side of the insulating housing relative to the connecting member, the connecting member defines the receiving room, and the retaining member defines the stopping structure.

10. The electrical connector assembly as claimed in claim 8, wherein the electrical connector has a connecting member disposed at a lateral side of the insulating housing, a retaining member disposed at another lateral side of the insulating housing relative to the connecting member and a cover pivoted to the connecting member and retained to the retaining member.

11. The electrical connector assembly as claimed in claim 10, wherein a space between the retaining member and the insulating housing is functioned as the receiving room, the connecting member or/and the cover defining the stopping structure.

12. The electrical connector assembly as claimed in claim 10, wherein the retaining member defines the receiving room, the connecting member or/and the cover defining the stopping structure.

13. The electrical connector assembly as claimed in claim 8, wherein the insulating housing has side walls extending upwardly, the clip having extending portions located at a peripheral area of the retaining mechanism and located at an outer side of the side walls, and the extending wall has an inclined guiding face for sliding along an outer side of the side wall in an assembling process.

14. An electrical connector assembly comprising:
a printed circuit board;
an electrical connector including:
an insulative housing mounted upon the printed circuit board and equipped with a plurality of terminals therein;
a connecting member mounted upon the printed circuit board and intimately located beside the housing in a front-to-back direction;
a retaining member mounted upon the printed circuit board an intimately located beside the housing in said front-to-back direction, said connecting member and said retaining member located by opposite sides of the housing to respectively retain opposite ends of a metallic rotatable cover either directly or indirectly; and
a clip carrying thereon a chip module which is received within the housing and downwardly pressed by the cover; wherein
a soft anti-mismating mechanism is formed between the chip module and the clip for guiding the user without physical prevention structure thereon, and a hard anti-mismating mechanism is formed between the clip and the connector with physical prevention structure thereon.

15. The electrical connector assembly as claimed in claim 14, wherein the hard anti-mismating mechanism includes a protruding portion of the clip dimensioned to be received in a receiving room defined in the connecting member without interference when the clip is correctly positioned/oriented with regard to the connector.

16. The electrical connector assembly as claimed in claim 15, wherein said protruding portion interferes with said retaining member or the associated cover when said clip is misplaced upon the housing in an incorrect opposite way.

17. The electrical connector assembly as claimed in claim 14, wherein said connecting member retains both the cover and a metallic rocking bar thereto, and said metallic rocking bar includes a crank section to which the cover is pivotally mounted, and said crank section is received in the receiving room

18. The electrical connector assembly as claimed in claim 14, wherein the retaining member is either engaged within a notch in the cover or is equipped with another metallic rocking bar to lock the cover in position.

19. The electrical connector assembly as claimed in claim 15, wherein the clip includes a pair of grabbing portions, of which one is adjacent to the protruding portion in the front-to-back direction.

20. The electrical connector assembly as claimed in claim 14, wherein said soft anti-mismating mechanism includes an indicating arrow printed upon a corner of the chip module, and another indicating arrow hollowed at a corresponding corner of the clip along a same diagonal direction.
